(19) United States
(12) Patent Application Publication
(10) Pub. No.: US 2025/0185440 A1
(43) Pub. Date: Jun. 5, 2025

(54) LIGHT-EMITTING DEVICE

(71) Applicant: EPISTAR CORPORATION, Hsinchu (TW)

(72) Inventors: Hsin-Ying WANG, Hsinchu (TW); Hui-Chun YEH, Hsinchu (TW); Jhih-Yong YANG, Hsinchu (TW); Siou-Huei YANG, Hsinchu (TW)

(21) Appl. No.: 18/962,207

(22) Filed: Nov. 27, 2024

(30) Foreign Application Priority Data
Nov. 30, 2023 (TW) 112146441

(51) Int. Cl. H10H 29/85; H10H 20/821; H10H 29/80

(52) U.S. Cl. CPC H10H 29/857; H10H 20/821; H10H 29/942

(57) ABSTRACT

A semiconductor device includes: a first light-emitting unit and a second light-emitting unit, wherein: the first light-emitting unit includes: a first lower semiconductor stack, including a first sub-sidewall; a first upper semiconductor stack, formed on the first lower semiconductor stack, including a second sub-sidewall; and a first sidewall, including the first sub-sidewall and the second sub-sidewall; wherein the first lower semiconductor stack includes a first upper surface not covered by the first upper semiconductor stack; the second light-emitting unit includes: a second lower semiconductor stack; a second upper semiconductor stack formed on the second lower semiconductor stack; wherein the second lower semiconductor stack includes a second upper surface not covered by the second upper semiconductor stack; a connecting electrode, formed on the first light-emitting unit and the second light-emitting unit and contacting the second upper surface to electrically connect the first light-emitting unit and the second light-emitting unit; and a first contact electrode, formed on the first upper surface and electrically connected to the first lower semiconductor stack, including a fist contact pad; wherein: the first sub-sidewall and the second sub-sidewall are directly connected to form a first slope; and in a top view, the second upper surface surrounds the second upper semiconductor stack.

### CROSS-REFERENCE TO RELATED APPLICATIONS

This application claims priority to and the benefit of Taiwan patent application No. 112146441 filed on Nov. 30, 2023, and the content of which is incorporated by reference in its entirety.

### BACKGROUND

### Technical Field

The present application relates to a light-emitting device and, more particularly, to a light emitting device having a plurality of light-emitting units.

### Description of the Related Art

The light-emitting diodes (LEDs) of solid-state lighting device have the characteristics of low power consumption, low heat-generation, long lifetime, compact size, and high response speed. Thus, the LEDs have been widely using in household appliance, lighting devices, indicating lamps, optical devices and the like. As the optical technique develops, solid-state lighting devices have great improvements in light-emitting efficiency, lifetime, and brightness.

A conventional LED chip includes a substrate, an n-type semiconductor layer, an active region, a p-type semiconductor layer formed on the substrate, and p-electrode and n-electrode respectively formed on the p-type and n-type semiconductor layers. By applying a specific forward voltage on the LED chip via the electrodes, holes from the p-type semiconductor layer and electrons from the n-type semiconductor layer are combined in the active region so as to emit light.

A high-voltage LED chip is a single chip which is divided into a plurality of light-emitting units electrically connected in series. Compared with the conventional LED chip, the high-voltage LED chip can be operated at low current and high voltage and has a large output power at the same chip size. The number and the size of the light-emitting units of the high-voltage LED chip can be determined in accordance with an input voltage, and each light-emitting unit can be optimized. The high-voltage LED chip has advantages of high voltage operation, small size, and flexibility of package design and optical design.

### SUMMARY

A semiconductor device includes: a first light-emitting unit and a second light-emitting unit, wherein: the first light-emitting unit includes: a first lower semiconductor stack, including a first sub-sidewall; a first upper semiconductor stack, formed on the first lower semiconductor stack, including a second sub-sidewall; and a first sidewall, including the first sub-sidewall and the second sub-sidewall; wherein the first lower semiconductor stack includes a first upper surface not covered by the first upper semiconductor stack; the second light-emitting unit includes: a second lower semiconductor stack; a second upper semiconductor stack formed on the second lower semiconductor stack; wherein the second lower semiconductor stack includes a second upper surface not covered by the second upper semiconductor stack; a connecting electrode, formed on the first light-emitting unit and the second light-emitting unit and contacting the second upper surface to electrically connect the first light-emitting unit and the second light-emitting unit; and a first contact electrode, formed on the first upper surface and electrically connected to the first lower semiconductor stack, including a fist contact pad; wherein: the first sub-sidewall and the second sub-sidewall are directly connected to form a first slope; and in a top view, the second upper surface surrounds the second upper semiconductor stack.

### BRIEF DESCRIPTION OF THE DRAWINGS

FIG. 1A shows a top view of a light-emitting device 1 in accordance with an embodiment of the present application.

FIG. 1B shows a cross-sectional view taken along A-A′ line in FIG. 1A.

FIG. 1C shows a cross-sectional view taken along B-B′ line in FIG. 1A.

FIG. 2A shows a top view of a light-emitting device 2 in accordance with another embodiment of the present application.

FIG. 2B shows a cross-sectional view taken along A-A′ line in FIG. 2A.

FIG. 2C shows a cross-sectional view taken along B-B′ line in FIG. 2A.

FIG. 3 shows a top view of a light-emitting device 3 in accordance with another embodiment of the present application.

FIG. 4A shows a first slope S1 in accordance with an embodiment of the present application.

FIG. 4B shows the first slope S1 in accordance with another embodiment of the present application.

FIG. 4C shows the first slope S1 in accordance with another embodiment of the present application.

FIGS. 5A-5C show a method of forming the first slope S1 in accordance with an embodiment of the present application.

FIG. 6 shows a light-emitting package 100 in accordance with an embodiment of the present application.

FIG. 7 shows a light-emitting module 200 in acc an embodiment of the present application.

### DETAILED DESCRIPTION

In order to make the description of the present application more detailed and complete, please refer to the description of the following embodiments and cooperate with the relevant illustrations. However, the examples shown below are used to illustrate the light-emitting device of the present application, and the present application is not limited to the following embodiments. In addition, the dimensions, materials, shapes, relative arrangements, etc. of the elements described in the embodiments in this specification are not limited to the description, and the scope of the present application is not limited to these, but is merely a description. In addition, the size or positional relationship of the elements shown in each figure is exaggerated for clear description. Furthermore, in the following description, in order to appropriately omit detailed descriptions, elements of the same or similar nature are shown with the same names and symbols.

A semiconductor device and a semiconductor module are provided in some embodiments of the present application. The semiconductor device in some embodiments may be semiconductor optoelectronic device, such as a light-emitting diode (LEDs), laser, light detector, solar cell, or power device. The primary structure of a semiconductor device includes a buffer layer and a device structure formed on the buffer layer. Different device structures may be formed depending on the device functions. For example, the device structure of a light-emitting device may be a semiconductor stack including a p-type semiconductor layer, an n-type semiconductor layer and an active region. The active region may emit light in different wavelength bands in accordance with the material composition. A plurality of embodiments is provided below as relevant descriptions of the semiconductor device and the semiconductor module, and it is understood that each semiconductor device in these embodiments is for illustrative purposes only instead of intending to limit the present disclosure.

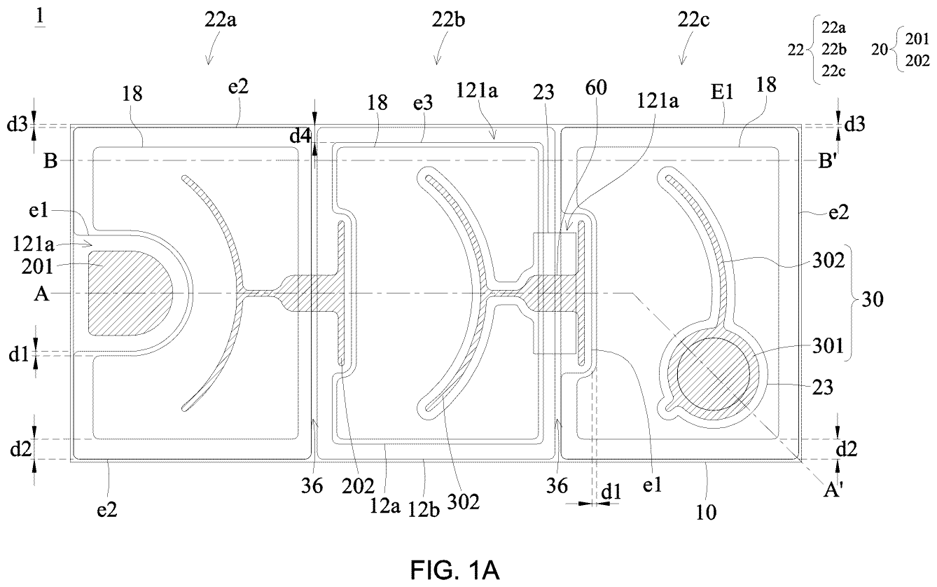

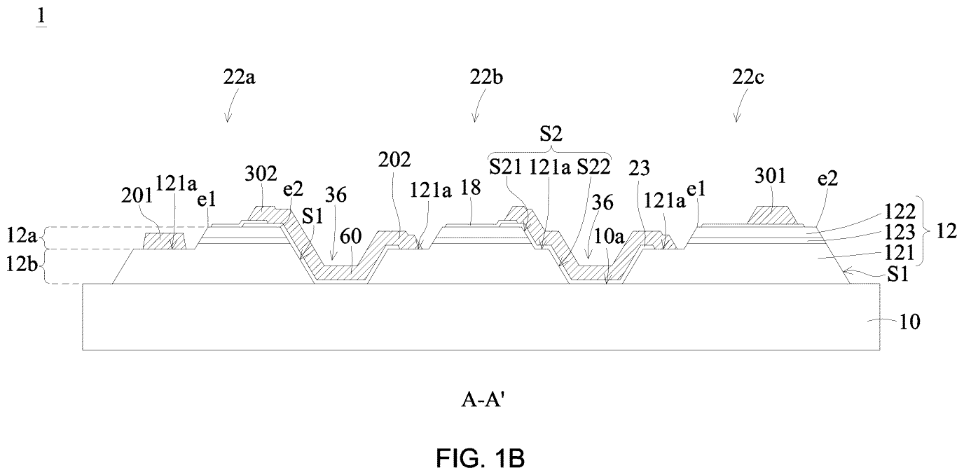

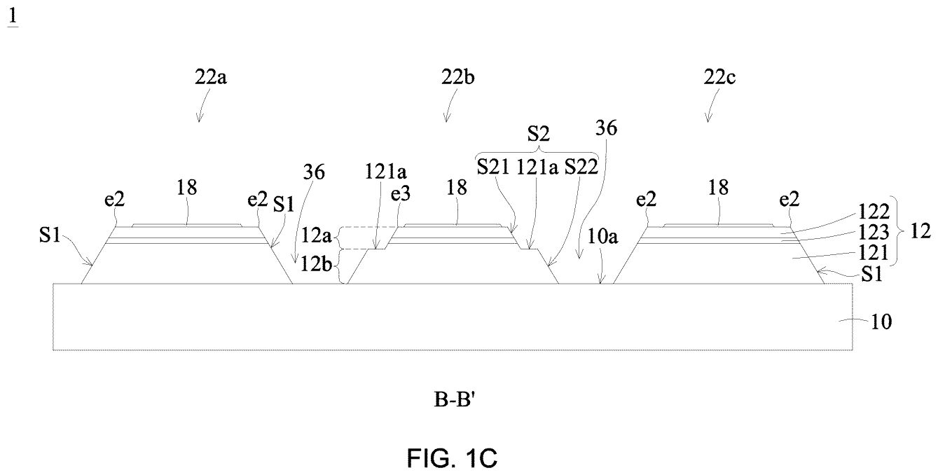

Referring to FIGS. 1A, 1B and 1C, in accordance with some embodiments, an embodiment of taking a light-emitting device 1 as the semiconductor device is illustrated. FIG. 1A shows a top view of a light-emitting device 1 in accordance with a first embodiment of the present application. FIG. 1B shows a cross-sectional view taken along A-A′ line in FIG. 1A. FIG. 1C shows a cross-sectional view taken along B-B′ line in FIG. 1A. As shown in FIGS. 1A-1C, the light-emitting device 1 includes a substrate 10 and a plurality of light-emitting units 22, such as a first light-emitting unit 22a, a second light-emitting unit 22b and a third light-emitting unit 22c, disposed on a top surface 10a of the substrate 10. Each light-emitting unit 22 includes a semiconductor stack 12 disposed on the substrate 10. The semiconductor stacks 12 of the plurality of light-emitting units 22 are separately from each other by trenches 36. The first light-emitting unit 22a, the second light-emitting unit 22b and the third light-emitting unit 22c are included in an embodiment of the plurality of light-emitting units 22. The number of the light-emitting units 22 is not limited thereto. The light-emitting device can include at least two light emitting units 22. An electrode structure is formed between adjacent light-emitting units 22 and on each light-emitting unit 22, and electrically connects the light-emitting units 22. In one embodiment, the plurality of light-emitting units 22 forms a series-connected light-emitting unit array. In the present embodiment, the starting light-emitting unit of the light-emitting unit array is the third light-emitting unit 22c, the end light-emitting unit is the first light-emitting unit 22a, and the middle light-emitting unit is the second light-emitting unit 22a.

The substrate 10 can be a growth substrate. The substrate 10 includes GaAs or GaP for growing AlGaInP based semiconductor thereon. The substrate 10 includes Al₂O₃, GaN, SiC or AlN for growing InGaN based or AlGaN based semiconductor thereon. In one embodiment, the substrate 10 can be a patterned substrate; that is, the substrate 10 includes patterned structures (not shown) on the top surface 10a. In one embodiment, the light generated from the semiconductor stack 12 is refracted, reflected or scattered by the patterned structures, thereby increasing the light extraction of the light-emitting device. In addition, the patterned structures lessen or suppress the dislocation caused by lattice mismatch between the substrate 10 and the semiconductor stack 12, thereby improving the epitaxy quality of the semiconductor stack 12.

In an embodiment of the present application, the semiconductor stack 12 is formed on the substrate 10 by metal-organic chemical vapor deposition (MOCVD), molecular beam epitaxy (MBE), hydride vapor epitaxy (HVPE) or ion plating such as sputtering or evaporating.

The semiconductor stack 12 includes a first semiconductor layer 121, an active region 123 and a second semiconductor layer 122 sequentially formed on the substrate 10. In one embodiment, the semiconductor stack 12 further includes a buffer structure (not shown) between the first semiconductor layer 121 and the substrate 10. The buffer structure reduces the lattice mismatch and suppresses dislocation, thereby improving epitaxy quality. The material of the buffer structure includes GaN, AlGaN, or AlN. In an embodiment, the buffer structure includes a plurality of sub-layers (not shown) and the sub-layers include the same materials or different materials. In one embodiment, the first semiconductor layer 121 and the second semiconductor layer 122 are, for example, cladding layers or confinement layers. The first semiconductor layer 121 and the second semiconductor layer 122 have different conductivity types, different electrical properties, different polarities or different dopants for providing electrons or holes. In one embodiment, the first semiconductor layer 121 includes n-type dopants and the second semiconductor layer 122 includes p-type dopants. For example, the first semiconductor layer 121 is composed of n-type semiconductor and the second semiconductor layer 122 is composed of p-type semiconductor. The active region 123 is formed between the first semiconductor layer 121 and the second semiconductor layer 122. When being driven by a current, electrons and holes are combined in the active region 123 to convert electrical energy into optical energy for illumination. The wavelength of the light generated by the light-emitting device 1 or by the semiconductor stack 12 can be adjusted by changing the physical properties and chemical composition of the semiconductor stack 12 such as one or more layers in the active region 123.

The material of the semiconductor stack 12 includes III-V compound semiconductor such as AlₓIn_{y}Ga_{(1-x-y)}N (i.e., AlInGaN base) or AlₓIn_{y}Ga_{(1-x-y)}P (i.e., AlInGaP base), where 0≤x, y≤1; x+y≤1. When the material of the semiconductor stack 12 includes AlInGaP based material, the semiconductor stack 12 emits red light having a wavelength between 610 nm and 650 nm or yellow light having a wavelength between 550 nm and 570 nm. When the material of the semiconductor stack 12 includes AlInGaN based material, the semiconductor stack 12 emits blue light or deep blue light having a wavelength between 400 nm and 490 nm, green light having a wavelength between 490 nm and 550 nm or UV light having a wavelength between 250 nm and 400 nm. The active region 123 can be a single hetero-structure (SH), a double hetero-structure (DH), a double-side double hetero-structure (DDH), or a multi-quantum well (MQW) structure. The material of the active region 123 can be i-type, p-type or n-type semiconductor.

In the present embodiment, the first semiconductor layer 121 includes an upper surface 121a that is not covered by the active region 123 and the second semiconductor layer 122. Therefore, the upper surface 121a can be an exposed area in the semiconductor stack 12. One portion of the semiconductor stack 12 above the upper surface 121a can be regarded as an upper semiconductor stack 12a, and the other portion of the semiconductor stack 12 below the upper surface 121a can be regarded as a lower semiconductor stack 12b. The upper surface 121a is also an upper surface of the lower semiconductor stack 12b. The sidewalls of the semiconductor stack 12, including the sidewalls of the upper semiconductor stack 12a and the lower semiconductor stack 12b, can be inclined to the top surface 10a of the substrate 10. In one embodiment, an included angle between the sidewalls of the semiconductor stack 12 and a horizontal plane (for example, the top surface 10a of the substrate) is less than 90 degrees. In one embodiment, the included angle ranges from 20 degrees to 80 degrees.

The electrode structure is provided on each light-emitting unit, including: a first contact electrode 20 electrically connected to the first semiconductor layer 121, a second contact electrode 30 electrically connected to the second semiconductor layer 122, and a connecting electrode 60 provided on two adjacent light-emitting units. 22. The contact electrodes can include pads and/or fingers. For example, the first contact electrode 20 includes a first contact pad 201 and/or a first finger 202, and the second contact electrode 30 includes a second contact pad 301 and/or a second finger 302. The first contact pad 201 is formed on the first semiconductor layer 121 of the first light-emitting unit 22a. The second contact pad 301 and second finger 302 is formed on the second semiconductor layer 122 of the third light-emitting unit 22c. Two ends of the connecting electrode 60 are respectively connected to the first finger 202 on one light-emitting unit 22 and the second finger 302 on another adjacent light-emitting unit 22, thereby electrically connecting each light-emitting unit 22. For example, the plurality of light-emitting units 22 forms a series-connected light-emitting unit array. In other embodiments, the connecting electrode 60 can connect the first fingers 202 on two adjacent light-emitting units 22, and/or the connecting electrode 60 can connect the second fingers 302 on two adjacent light-emitting units 22, so that the plurality of light-emitting units 22 forms different light-emitting unit arrays such as parallel connection, series connection or series-parallel connection. In the present embodiment, the first contact pad 201 on the first light-emitting unit 22a and the second contact pad 301 on the third light-emitting unit 22c can be used for wiring in subsequent processes, so that the light-emitting device 1 can be connected to an external electronic component or a power source. The electrode structure includes metal materials, such as chromium (Cr), titanium (Ti), tungsten (W), gold (Au), aluminum (Al), rhodium (Rh), indium (In), tin (Sn), nickel (Ni), platinum (Pt), silver (Ag) and other metals, a laminated stack or an alloy of the above materials. In one embodiment, the first contact electrode 20, the second contact electrode 30 and the connecting electrode 60 can be formed in the same process and include the same material, but are not limited thereto.

Trenches 36 located between two adjacent light-emitting units 22. A bottom of the trench 36 includes the top surface 10a of the substrate 10, and sidewalls of the trench 36 is defined by the two sidewalls facing each other of the two adjacent light-emitting units 22. The light-emitting device 1 includes a current blocking structure 23 located below the electrode structure. In the present embodiment, the current blocking structure 23 is located below the connecting electrode 60 and covers the trenches 36. More specifically, the current blocking structure 23 covers the top surface 10a of the substrate 10 in the trench 36 and the sidewalls close to the trench 36 of two adjacent light-emitting units 22. The current blocking structure 23 can further extend onto the semiconductor stack 12 of the light emitting unit 22. The current blocking structure 23 can also be disposed below the second finger 302. In one embodiment, the current blocking structure 23 disposed in the trench and extending onto the semiconductor stack 12 of the light emitting unit 22 can be connected to the current blocking structure 23 disposed below the second finger 302. In one embodiment, as shown in FIGS. 1A and 1B, the current blocking structure 23 can also be provided below the second finger 302 and the second contact pad 301 on the third light-emitting unit 22c. In other embodiments (not shown), the current blocking structure 23 can also be provided under the first finger 202 and/or the first contact pad 201 of the light-emitting unit 22 in accordance with the requirement of electrical or optical performance.

The material of the current blocking structure 23 includes transparent insulating materials, such as silicon oxide, silicon nitride, silicon oxynitride, niobium oxide, hafnium oxide, titanium oxide, magnesium fluoride, aluminum oxide, and the like, a combination or a laminated stack of the above materials. The current blocking structure 23 includes single layer or a stack of a plurality pairs of insulating layers. In one embodiment, each pair of insulating layers includes two sub-layers. The two sub-layers are composed of insulating materials with different refractive indexes. The current blocking structure 23 includes distributed Bragg reflector.

The light-emitting device 1 includes a transparent conductive layer 18 formed on and electrically connected to the second semiconductor layer 122 of each light-emitting unit 22. The transparent conductive layer 18 can spread current and provide good electrical contact with the second semiconductor layer 122, such as ohmic contact. The transparent conductive layer 18 covers part of the current blocking structure 23. The current blocking structure 23 prevents current from being conducted by the electrode structure and directly injecting into the semiconductor stack 12. Instead, current diffuses horizontally through the transparent conductive layer 18 above the current blocking structure 23 so that current spreading can be improved. The transparent conductive layer 18 is transparent to the light emitted by the active region 123, and has a transmittance of more than 80%, for example. The material of the transparent conductive layer 18 can be a metal or a transparent conductive material. The metal material includes Au, NiAu, etc. The transparent conductive material includes graphene, ITO, AZO, GZO, ZnO, IZO and other materials.

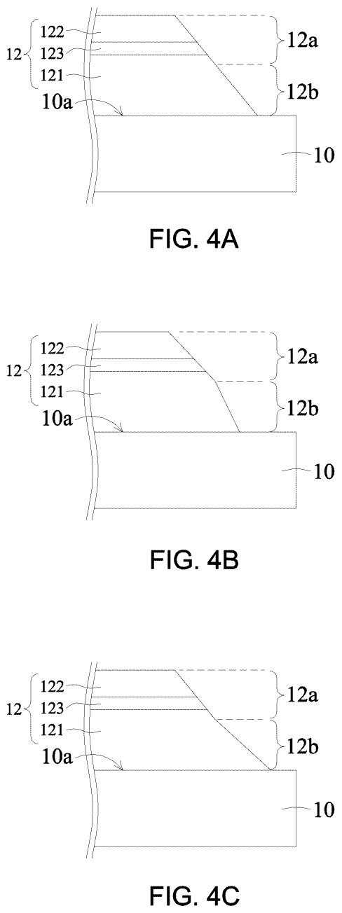

The configuration of the upper surface 121a of the first semiconductor layer 121 in one of the starting light-emitting unit and the end light-emitting unit is different from that of the middle light-emitting units. The details will be described in the following. In the present embodiment, as shown in FIGS. 1A to 1C, the upper surface 121a of the first semiconductor layer 121 in the second light-emitting unit 22b includes a contact area located below the first finger 202 and a surrounding area surrounding the upper semiconductor stack 12a. Therefore, viewed from the cross-sections of FIGS. 1B and 1C, the upper surface 121a of the first semiconductor layer 121 of the second light-emitting unit 22b is located between the sidewall S22 of the lower semiconductor stack 12b and the sidewall S21 of the upper semiconductor stack 12a. The sidewall S21, the upper surface 121a of the first semiconductor layer 121 and the sidewall S22 constitute the sidewall S2 of the semiconductor stack 12 of the second light-emitting unit 22b. That is, the sidewall S2 of the semiconductor stack 12 of the second light-emitting unit 22b has a step shape. Different from the second light-emitting unit 22b, in one of the first light-emitting unit 22a and the third light-emitting unit 22c, the upper surface 121a of the first semiconductor layer only includes contact area where the first contact pad 201 and/or first finger 202 is disposed on, and does not have surrounding area surrounding its upper semiconductor stack 12a. In this way, a larger active region 123 can be obtained in the first light-emitting unit 22a and/or the third light-emitting unit 22c, thereby increasing the light-emitting area. In the cross-section views of FIGS. 1B and 1C, the sidewalls of the lower semiconductor stack 12b and the upper semiconductor stack 12a of the first light-emitting unit 22a are directly connected to each other to form the first slope S1, and the third light-emitting unit 22c includes the same configuration as the first light-emitting unit 22a. In other words, in one of the first light-emitting unit 22a and the third light-emitting unit 22c, the sidewall of the lower semiconductor stack 12b and the sidewall of the upper semiconductor stack 12a can be regarded as sub-sidewalls of the semiconductor stack 12. The first slope S1 extends downward from a top surface of the upper semiconductor stack 12a to the bottom surface of the lower semiconductor stack 12b. FIGS. 4A to 4C show different embodiments of the first slope S1. As shown in FIG. 4A, the first slope S1 is a continuous slope, and the joint between the sidewall of the lower semiconductor stack 12b and the sidewall of the upper semiconductor stack 12a is continuous without turning. That is, the sidewalls of the lower semiconductor stack 12b and the upper semiconductor stack 12a have substantially the same slope. In another embodiments, as shown in FIG. 4B and FIG. 4C, the first slope S1 is a continuous slope, and the joint between the sidewall of the lower semiconductor stack 12b and the sidewall of the upper semiconductor stack 12a is a continuous slope with a turning. That is, the sidewalls of the lower semiconductor stack 12b and the upper semiconductor stack 12a have different slopes. In one embodiment, the difference in slopes between the sidewalls of the lower semiconductor stack 12b and the upper semiconductor stack 12a is not greater than 10%. The first slope S1 can include a convex curved surface or a concave curved surface.

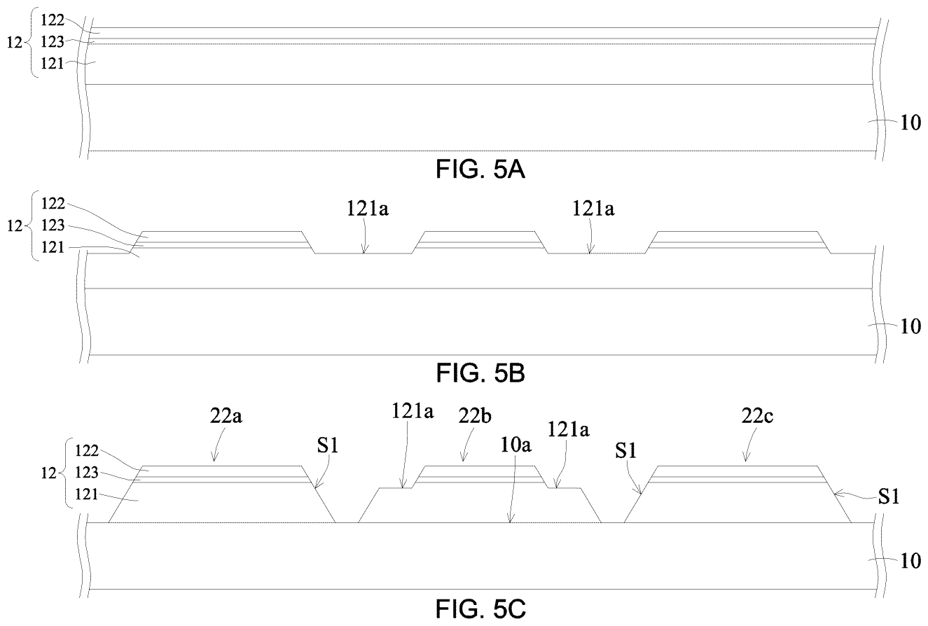

In one embodiment of manufacturing the light-emitting device 1, the semiconductor stack 12 can be etched from the top surface of the second semiconductor layer 122 to the top surface 10a of the substrate 10 to form the continuous first slope S1. In another embodiment, multiple etching steps can be performed. As shown in FIGS. 5A to 5C, in a first etching, the semiconductor stack 12 is etched from the top surface of the second semiconductor layer 122 downward until the upper surface 121a of the first semiconductor layer 121 is formed, and then in a second etching, the first semiconductor layer 122 is etched from the upper surface 121a downward to the top surface 10a of the substrate 10, to form a continuous first slope S1. In the light-emitting units 22a and 22c having the first slope S1, a portion of the upper surface 121a of the first semiconductor layer 121 is reserved as the contact area for forming the first contact electrode 20 thereon.

In the top view, the light-emitting device 1 and each one of the light-emitting units 22 have a polygonal shape, for example, a quadrilateral shape. In the present embodiment shown in FIG. 1A, the light-emitting device 1 has a quadrilateral shape, such as a rectangle, and the substrate 10 includes four edges with one of which, such as the long side, is marked E1. Each light-emitting unit 22 has a quadrangular shape, such as a rectangle, and the rectangle has a first side, a second side, a third side and a fourth side. Both E1 and its opposite long side are adjacent to one side of each light-emitting unit 22. The first slopes S1 are located on the first side, the second side, the third side and/or the fourth side of one of the first light-emitting unit 22a and the third light-emitting unit 22c. That is, the configuration with the sidewall of the lower semiconductor stack 12b and the sidewall of the upper semiconductor stack 12a are directly connected to each other can be formed on the first side, the second side, the third side and/or the fourth side of the rectangle. In the first light-emitting unit 22a and/or the third light-emitting unit 22c, the edge of the upper semiconductor stack 12a includes a first portion e1 adjacent to and connected to the first upper surface 121a, and a second portion e2 connected to the first slope S1 and substantially parallel to an edge of the substrate 10. In the second light-emitting unit 22b, the edge of the upper semiconductor stack 12a is marked e3. The minimum distance d3 between e2 and E1 may not be equal to the minimum distance d4 between e3 and E1. In one embodiment, the minimum distance d3 between e2 and E1 is smaller than the minimum distance d4 between e3 and E1. E1 is taken as an example in the embodiment described above. Although d3 and d4 are not marked near the opposite long side of E1, those skilled in the art can understand that the opposite long side of E1 can also have the same configuration.

In the top view, in any one of the light-emitting unit 22, a distance is set between the edge of the transparent conductive layer 18 and the edge of the upper semiconductor stack 12a, and the distance can be constant or not constant. In addition, the distances in each light-emitting unit 22 can be the same or different. For example, in one embodiment, in the second light-emitting unit 22b shown in FIG. 1A, the edge of the transparent conductive layer 18 is indented from the edge e3 of the upper semiconductor stack 12a at a constant distance. In the first light-emitting unit 22a and/or the third light-emitting unit 22c, the edge of the transparent conductive layer 18 may be indented from the edge of the upper semiconductor stack 12a at a constant distance or a non-constant distance. In one embodiment, at a position in the transparent conductive layer 18 adjacent to the first slope S1, the distance between the edge of the transparent conductive layer 18 and the edge of the upper semiconductor stack 12a can be widened. For example, the above-mentioned distance close to the upper surface 121a of the first semiconductor 121 is smaller than the above-mentioned distance located in other areas. That is, as shown in FIG. 1A, the distance d1 between the transparent conductive layer 18 and the first portion e1 is smaller than the distance d2 between the transparent conductive layer 18 and the second portion e2. In one embodiment, the distance d1 ranges between 0-10 μm. Similarly, in the third light-emitting unit 22c, the distance d1 between the transparent conductive layer 18 and the first portion e1 is smaller than the distance d2 between the transparent conductive layer 18 and the second portion e2. In this way, the semiconductor stack 12 can be prevented from being over-etched due to process variation during the formation of the first slope S1. The process variation may cause the edge of the transparent conductive layer 18 to exceed or be aligned with the edge of the upper semiconductor stack 12a. In accordance with the present embodiment, process tolerance can be increased. In one embodiment, in the second light-emitting unit 22b, the distance between the transparent conductive layer 18 and the edge e3 of its upper semiconductor stack 12a is smaller than d2 in the first light-emitting unit 22a or the third light-emitting unit 22c.

In generally, contact pads are provided on the starting and the end light-emitting units in the light-emitting unit array, forming a light-shielding area on the starting and ending light-emitting units. In the embodiment of the present application, the upper surface 121a of the first semiconductor layer 121 of the starting light-emitting unit or/and the end light-emitting unit does not have the surrounding area surrounding the upper semiconductor stack 12a, so that the sidewall of the lower semiconductor stack 12b and the sidewall of the upper semiconductor stack 12a are directly connected to each other to form the first slope S1. Thereby, a larger area of the active region 123 can be obtained in the starting light-emitting unit and/or the end light-emitting unit, increasing the total light-emitting area, and making the brightness and current density within each light-emitting unit of the light-emitting device 1 more uniform. In addition, in order to dispose the first contact pad 201 on the end light-emitting unit, which requires a larger area of the first upper surface 121a, so the light-emitting area may be sacrificed in the end light-emitting unit (the light-emitting area can be regarded as the area of the upper semiconductor stack 12a). When the size of the light-emitting device becomes smaller, the impact of the loss of the light-emitting area on the brightness is more significant. The loss of light-emitting area can be compensated by enlarging the overall area of the end light-emitting unit (the overall area can be regarded as the area of the lower semiconductor stack). Nevertheless, in a light-emitting device with a fixed size, if an area of one light-emitting unit is enlarged, then an area of any other light-emitting units is reduced. This causes, for example, different current densities in the light-emitting units, which affects the optoelectronic characteristics and even the life of the light-emitting device. In this embodiment, without adjusting the areas of other light-emitting units, the light-emitting area of the end light-emitting unit can be made more consistent with the light-emitting areas of other light-emitting units. In one embodiment, a difference in areas between the upper semiconductor stack 12a of the first light-emitting unit 22a (and/or the third light-emitting unit 22c) and the upper semiconductor stack 12a of the second light-emitting unit 22b is less than or equal to 15%.

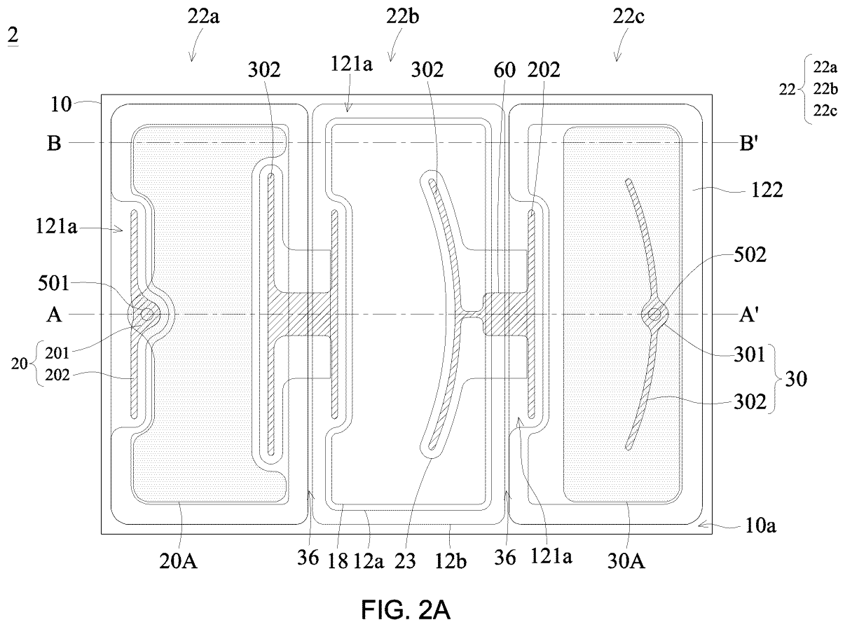

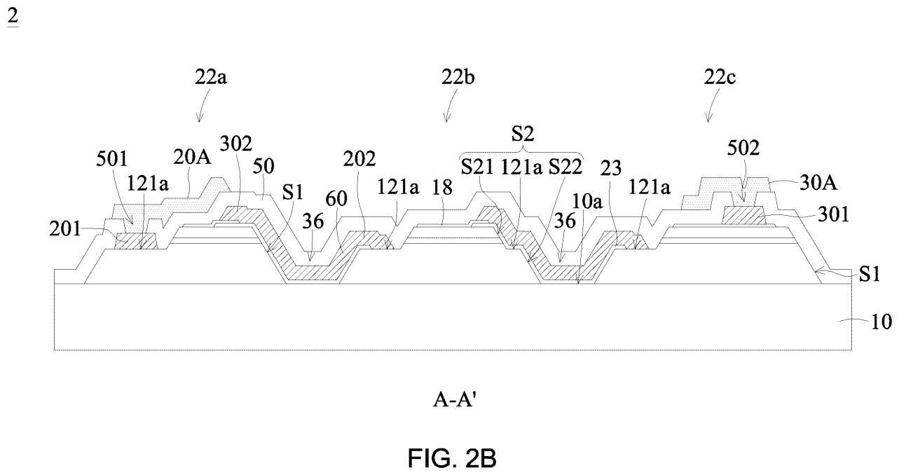

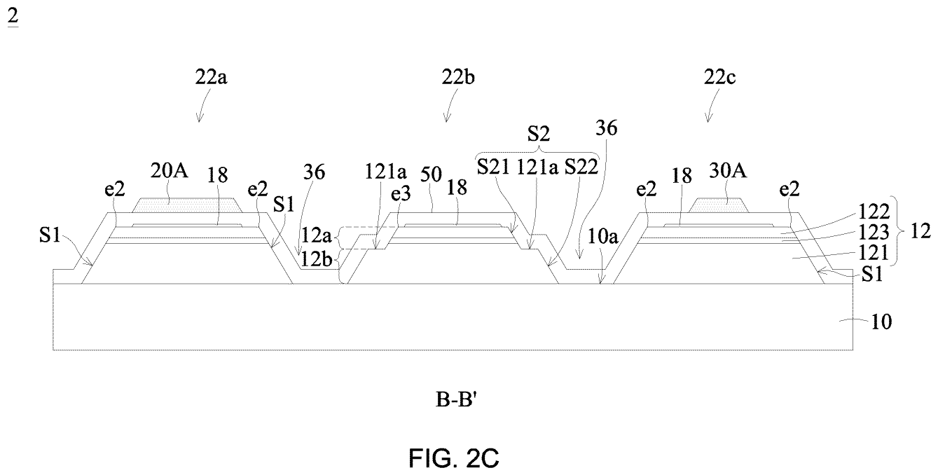

FIG. 2A shows a top view of a light-emitting device 2 in accordance with another embodiment of the present application. FIG. 2B shows a cross-sectional view taken along A-A′ line in FIG. 2A. FIG. 2C shows a cross-sectional view taken along B-B′ line in FIG. 2A. The light-emitting device 2 is similar to the light-emitting device 1 and includes a plurality of light-emitting units 22 electrically connected in series through electrode structures to form a light-emitting unit array. In this embodiment, the starting light-emitting unit of the light-emitting unit array is the third light-emitting unit 22c, and the end light-emitting unit is the first light-emitting unit 22a. If the details of each elements of the light-emitting device 2, such as material, thickness, sidewall angle, are not specifically described in this embodiment and have the same name and same label as those of the light-emitting device 1, the details can be referred to the description of the light-emitting device 1, and will not be repeated. The differences between the light-emitting device 2 and the light-emitting device 1 are described in the following.

The light-emitting device 2 includes an insulating structure 50 covering the light-emitting units 22 and the trenches 36. The insulating structure 50 includes openings 501 and 502 respectively exposing the first contact pad 201 on the first light-emitting unit 22a and the second contact pad 301 on the third light-emitting unit 22c. A first bonding pad 20A is located on the insulating structure 50 and filled in the opening 501 to connect to the first contact electrode 20. A second bonding pad 30A is located on the insulating structure 50 and filled in the opening 502 to connect to the second contact electrode 30. In the present embodiment, the contact pads 201 and 301 are not used for wiring, but are used as contact portions connected to the bonding pads 20A and 30A respectively. The insulating structure 50 includes insulating material, such as silicon oxide, silicon nitride, silicon oxynitride, niobium oxide, hafnium oxide, titanium oxide, magnesium fluoride, aluminum oxide, etc. The insulation structure 50 can be a multi-layer structure or a single-layer structure. In the embodiment that the insulation structure 50 includes a multi-layer structure (not shown), the insulation structure 50 includes multiple pairs of insulation layers with different refractive indexes stacked alternately which can reflect light within a specific wavelength range and/or a specific incident angle range. The insulating structure 50 can be used as a reflective structure, such as a distributed Bragg reflector, so that the light emitted by the semiconductor stack is extracted from surfaces of the substrate 10. The first bonding pad 20A and the second bonding pad 30A can provide a current path for an external power source to supply power to the first semiconductor layer 121 and the second semiconductor layer 122. The first bonding pad 20A and the second bonding pad 30A of the light-emitting device 2 are bonded to a carrier (not shown) through a conductive bonding layer (not shown) in a flip-chip manner. The bonding pads 20A and 30A include metal materials, such as chromium (Cr), titanium (Ti), tungsten (W), gold (Au), aluminum (Al), indium (In), tin (Sn), nickel (Ni), platinum (Pt), silver (Ag) and other metals, a laminated stack or an alloy of the above materials. In one embodiment, the bonding method includes but not limited to solder bonding, wherein the conductive bonding layer includes but is not limited to solder or conductive glue.

In the present embodiment, like the light-emitting device 1, in the second light-emitting unit 22b shown in FIGS. 2A to 2C, the upper surface 121a of the first semiconductor layer 121 includes a contact area under the finger 202 and a surrounding area surrounding the upper semiconductor stack 12a. Therefore, the sidewall S2 of the semiconductor stack 12 of the second light-emitting unit 22b has a step shape in a cross-sectional view. In one of the first light-emitting unit 22a and the third light-emitting unit 22c, the upper surface 121a of the first semiconductor layer 121 includes a contact area under the first contact electrode 20 (the first finger 202 and/or the first contact pad 201), and does not have a surrounding area surrounding the upper semiconductor stack 12a. Therefore, in the cross-sectional views of FIGS. 2B and 2C, the sidewalls of the lower semiconductor stack 12b and the upper semiconductor stack 12a in one of the first light-emitting unit 22a and the third light-emitting unit 22c are directly connected to each other to form the first slope S1. The first slope S1 extends downward from the top surface of the upper semiconductor stack 12a to the bottom surface of the lower semiconductor stack 12b. In this way, a larger light-emitting area (an area of the upper semiconductor stack 12a) can be obtained in the starting light-emitting unit and/or the end light-emitting unit. In the present embodiment, the bonding pads 20A and/or 30A are disposed on the upper semiconductor stacks 12a with larger areas of the starting light-emitting unit and the end light-emitting unit, so the bonding pads can also have larger areas, improving the yield of subsequent flip-chip bonding process of light-emitting device.

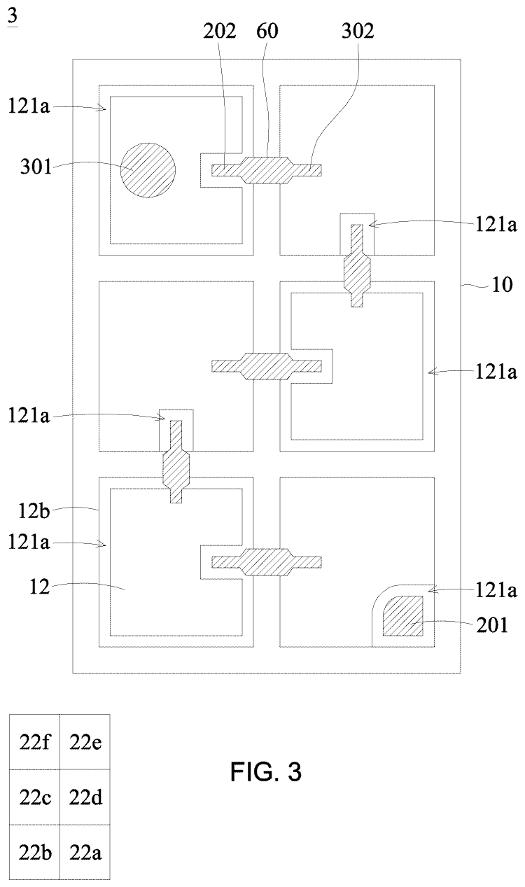

In the embodiments described above, three light-emitting units 22 arranged in a single row (or single column) are used as an example. However, the embodiments in the present application is not limited thereto. Different numbers and different arrangements of the plurality of light-emitting units can be designed in accordance with operating voltages and sizes of the light-emitting devices. FIG. 3 shows a top view of a light-emitting device 3 in accordance with another embodiment of the present application. As shown in FIG. 3, the light-emitting device 3 includes a plurality of light-emitting units 22a to 22f electrically connected in series. The elements which are the same as those in the previous embodiments, such as the transparent conductive layer 18, the current blocking structure 23, etc., are not shown in FIG. 3. In the light-emitting units 22a, 22c, and 22e, the upper surfaces 121a of the first semiconductor layers 121 include the contact area under the first finger 202 and the first contact pad 201, and do not have the surrounding area surrounding the upper semiconductor stack 12a. Therefore, like the previous embodiment, the sidewalls of the lower semiconductor stack and the sidewall of the upper semiconductor stack of the one of the light-emitting units 22a, 22c, 22e are directly connected to each other to form the first slopes S1. In the light-emitting units 22b, 22d, and 22f, the upper surfaces 121a of the first semiconductor layers 121 includes both the contact areas under the first finger 202 and the surrounding area surrounding the upper semiconductor stack. Therefore, the sidewall of the semiconductor stack of each of the light-emitting units 22b, 22d, and 22f form a step shape. Although the cross-sectional view of the light-emitting device 3 is not shown, those skilled in the art can understand the cross-sectional structure of the semiconductor stack 12 of the light-emitting device 3 through the previous embodiments. Similarly, in another embodiment, the light-emitting device 3 can also include the insulating structure 50 and the bonding pads 20A and 30A as described in the embodiment of the light-emitting device 2.

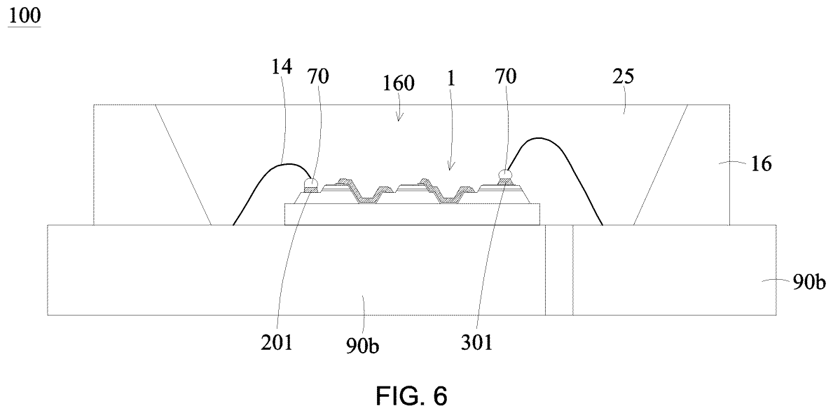

FIG. 6 shows a light-emitting package 100 in accordance with an embodiment of the present application. As shown in FIG. 6, the light-emitting package 100 includes a body 16 with a cavity 160, first and second lead frames 90a and 90b, wires 14, solder balls 70, encapsulation element 25 and the light-emitting device in accordance with any one embodiment of the present application, such as light-emitting device 1. The cavity 160 can be an opening which is sunken from a top surface of the main body 16. In one embodiment, the inner sidewalls of the main body 16 constituting the cavity 160 can include reflective structures (not shown). The first lead frame 90a and the second lead frame 90b are spaced apart from each other. The light-emitting device 1 is disposed in the cavity 160 on at least one of the first and second lead frames 90a and 90b. For example, the light-emitting device 1 is disposed on the first lead frame 90a, and the first contact pad 201 and the second contact pad 301 of the light-emitting device 1 are electrically connected to the first and second lead frame respectively by the wires 14 and the solder balls 70. The encapsulation element 25 is disposed in the cavity 160 and covers the light-emitting device. The encapsulation element 25 includes, for example, silicone resin or epoxy resin, and its structure can be a single layer or multiple layers. In one embodiment, the encapsulation element 25 can further include wavelength conversion element for converting the wavelength of the light generated by the light-emitting device, such as phosphor and/or scattering material.

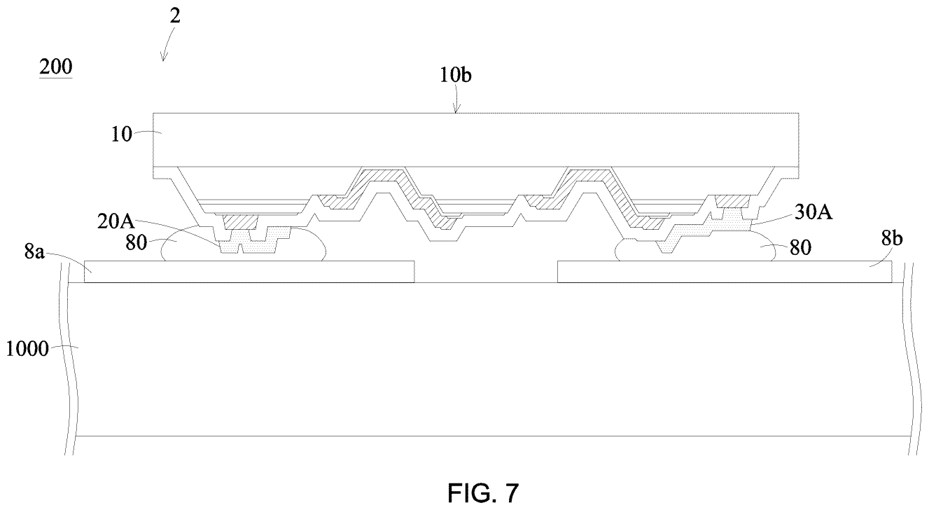

FIG. 7 shows a light-emitting module 200 in accordance with an embodiment of the present application. The light-emitting module 200 includes a carrier 1000. The carrier 1000 is provided with circuit bonding pads 8a and 8b. The bonding pads 20A and 30A of the light-emitting device in accordance with any embodiment of the present application, such as the light-emitting device 2, are respectively bonded to the circuit bonding pads 8a and 8b via the conductive bonding layer 80. In one embodiment, the bonding method includes but is not limited to solder bonding or glue bonding, wherein the conductive bonding layer 80 includes solder or conductive glue. As a result, the light emitted by the semiconductor stack 12 can be extracted from the bottom surface 10b and side surfaces of the substrate 10. In one embodiment, the light-emitting module 200 further includes an encapsulation element (not shown) located on the carrier 1000 to cover the light-emitting device 2. The encapsulation element includes silicone, epoxy, acrylic or a combination thereof. In one embodiment, the light-emitting device 2 further includes a reflective structure (not shown) disposed on the bottom surface 10b of the substrate 10 to reflect the light emitted by the semiconductor stack 12 so that most of the light can be extracted from the side surface of the substrate 10. The detailed structure of the reflective structure can be the same as the insulating structure 50 of the aforementioned embodiments.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A semiconductor device, comprising:
a first light-emitting unit and a second light-emitting unit, wherein:
the first light-emitting unit comprises:
a first lower semiconductor stack, comprising a first sub-sidewall;
a first upper semiconductor stack, formed on the first lower semiconductor stack, comprising a second sub-sidewall; and
a first sidewall, comprising the first sub-sidewall and the second sub-sidewall;
wherein the first lower semiconductor stack comprises a first upper surface not covered by the first upper semiconductor stack;
the second light-emitting unit comprises:
a second lower semiconductor stack;
a second upper semiconductor stack formed on the second lower semiconductor stack;
wherein the second lower semiconductor stack comprises a second upper surface not covered by the second upper semiconductor stack;
a connecting electrode, formed on the first light-emitting unit and the second light-emitting unit and contacting the second upper surface to electrically connect the first light-emitting unit and the second light-emitting unit; and
a first contact electrode, formed on the first upper surface and electrically connected to the first lower semiconductor stack, comprising a fist contact pad;
wherein:
the first sub-sidewall and the second sub-sidewall are directly connected to form a first slope; and
in a top view, the second upper surface surrounds the second upper semiconductor stack.

2. The semiconductor device of claim 1, further comprising a substrate with an edge, wherein the first light-emitting unit and the second light-emitting unit are separately disposed on the substrate; and the first sidewall is adjacent to the edge of the substrate.

3. The semiconductor device of claim 2, wherein the first upper semiconductor stack comprises a first edge, the second upper semiconductor stack comprises a second edge, and the first edge and the second edge are parallel with each other and adjacent to the edge of the substrate; and
wherein in the top view, a distance between the first edge and the edge of the substrate is smaller than a distance between the second edge and the edge of the substrate.

4. The semiconductor device of claim 1, further comprising a transparent conductive layer formed on the first upper semiconductor stack;
wherein in the top view, the first upper semiconductor stack comprises a third edge adjacent to the first upper surface and a fourth edge connected to the first sidewall; and
wherein a distance between the transparent conductive layer and the third edge is smaller than a distance between the transparent conductive layer and the fourth edge.

5. The semiconductor device of claim 1, further comprising a third light-emitting unit electrically connected to the second light-emitting unit, wherein the third light-emitting unit comprises:
a third lower semiconductor stack, comprising a third sub-sidewall;
a third upper semiconductor stack formed on the third lower semiconductor stack, comprising a fourth sub-sidewall; and
a third sidewall, comprising the third sub-sidewall and the fourth sub-sidewall;
wherein:
the third lower semiconductor stack comprises a third upper surface not covered by the third upper semiconductor stack;
the third sub-sidewall and the fourth sub-sidewall are directly connected to form a second slope; and
the second light-emitting unit is formed between the first light-emitting unit and the third light-emitting unit.

6. The semiconductor device of claim 5, further comprising a second contact electrode formed on the third light-emitting unit and electrically connected to the third upper semiconductor stack, wherein the second contact electrode comprises a second contact pad.

7. The semiconductor device of claim 5, further comprising a transparent conductive layer formed on the third upper semiconductor stack;
wherein the third upper semiconductor stack comprises a fifth edge adjacent to the third upper surface and a sixth edge connected to the third sidewall; and
wherein a distance between the transparent conductive layer and the fifth edge is smaller than a distance between the transparent conductive layer and the sixth edge.

8. The semiconductor device of claim 6, further comprising:
an insulating structure, formed on the first light-emitting unit, the second light-emitting unit and the third light-emitting unit, comprising an opening on the second contact pad; and
a second bonding pad, formed on the insulating structure, filled in the opening and connecting the second contact pad.

9. The semiconductor device of claim 1, wherein a difference in areas between the first upper semiconductor stack and the second upper semiconductor stack is less than or equal to 15%.

10. The semiconductor device of claim 1, further comprising:
an insulating structure, formed on the first light-emitting unit and the second light-emitting unit, comprising an opening on the first contact pad; and
a first bonding pad, formed on the insulating structure, filled in the opening and connecting the first contact pad.

11. The semiconductor device of claim 10, wherein the first contact electrode further comprises a first finger, wherein the first bonding pad does not overlap the first finger.

12. The semiconductor device of claim 10, further comprising a second contact electrode formed on the first upper semiconductor stack, wherein the second contact electrode comprises a second finger and the first bonding pad does not overlap the second finger.

13. The semiconductor device of claim 1, wherein in the top view, the first light-emitting unit comprises a quadrilateral shape, wherein the quadrilateral shape comprises a first side, a second side, a third side and a fourth side; and
the first sidewall is located on the first side, the second side, the third side and the fourth side.

14. The semiconductor device of claim 1, wherein the first slope extends downward from a top surface of the upper semiconductor stack to a bottom surface of the lower semiconductor stack.

15. The semiconductor device of claim 1, wherein the first slope is continuous without a turning.

16. The semiconductor device of claim 1, wherein the first sub-sidewall and the second sub-sidewall have different slopes, and a difference in slopes between the first sub-sidewall and the second sub-sidewall is not greater than 10%.

17. The semiconductor device of claim 16, wherein the first slope comprises a convex curved surface or a concave curved surface

18. The semiconductor device of claim 1, wherein the first sidewall faces the second light-emitting unit.

19. The semiconductor device of claim 1, wherein in the top view, the second light-emitting unit comprises a quadrilateral shape, wherein the quadrilateral shape comprises a first side, a second side, a third side and a fourth side; and
the second light-emitting unit comprises a second sidewall, and the second sidewall comprises a step shape located on the first side, the second side, the third side and the fourth side.

20. A semiconductor module, comprising:
the semiconductor device according to claim 1;
a carrier; and
a circuit bonding pad, formed on the carrier;
wherein the semiconductor device is bonded to the carrier and electrically connected to the circuit bonding pad.
